(19) United States
(12) Patent Application Publication
(10) Pub. No.: US 2025/0323084 A1
(43) Pub. Date: Oct. 16, 2025

(54) HEATER FOR SEMICONDUCTOR MANUFACTURING APPARATUS

(71) Applicant: NGK INSULATORS, LTD., Nagoya-City (JP)

(72) Inventors: Yutaka UNNO, Handa-Shi (JP); Keita YAMANA, Nagoya-Shi (JP); Kazuhiro NOBORI, Handa-Shi (JP)

(73) Assignee: NGK INSULATORS, LTD., Nagoya-City (JP)

(21) Appl. No.: 19/072,047

(22) Filed: Mar. 6, 2025

(30) Foreign Application Priority Data
Apr. 10, 2024 (WO) PCT/JP2024/014568
Nov. 25, 2024 (JP) 2024-204673

(51) Int. Cl. H01L 21/687; H01J 37/32

(52) U.S. Cl. CPC H01L 21/68757; H01J 37/32724; H01J 2237/332; H01J 2237/334

(57) ABSTRACT

A heater for a semiconductor manufacturing apparatus includes a ceramic base and a heating element. The ceramic base contains aluminum nitride. The heating element is embedded in the ceramic base. The ceramic base contains two or more kinds of rare earth elements and contains Yb as one of the rare earth elements. A total content ratio of the rare earth elements in the ceramic base is 4.5 mass % or less in terms of oxide. A content ratio of Yb in the ceramic base is 0.3 mass % or more and 1.3 mass % or less in terms of oxide.

This application claims priority under 35 U.S.C. Section 119 to International Application PCT/JP2024/014568 filed on Apr. 10, 2024 and Japanese Patent Application No. 2024-204673 filed on Nov. 25, 2024, the contents of which are hereby incorporated by reference into this application.

### BACKGROUND OF THE INVENTION

### 1. Field of the Invention

The present invention relates to a heater for a semiconductor manufacturing apparatus.

### 2. Description of the Related Art

A heater for a semiconductor manufacturing apparatus that supports and heats a semiconductor substrate has heretofore been used in semiconductor device manufacturing. The heater for a semiconductor manufacturing apparatus typically includes a ceramic base and a heating element embedded in the ceramic base.

As such heater for a semiconductor manufacturing apparatus, for example, a ceramic heater including a heating element containing a metal, such as molybdenum (Mo) or tungsten (W), and a ceramic base containing 91 wt % to 99 wt % of aluminum nitride and 1 wt % to 9 wt % of a rare earth element oxide has been proposed (see Japanese Patent Application Laid-open No. 2002-141163).

### SUMMARY OF THE INVENTION

In the heater for a semiconductor manufacturing apparatus such as the ceramic heater described in Japanese Patent Application Laid-open No. 2002-141163, it has been desired to increase the thermal conductivity of the ceramic base. Accordingly, addition of a rare earth element oxide to the ceramic base has been investigated to increase the thermal conductivity of the ceramic base.

However, simple addition of a large amount of the rare earth element oxide to the ceramic base increases the difference between the linear expansion coefficient of the ceramic base and the linear expansion coefficient of the heating element, and hence breakage such as a crack may occur in the ceramic base during manufacturing of the heater for a semiconductor manufacturing apparatus. Accordingly, there is room for improvement balancing improvement of the volume resistivity of the ceramic base and manufacturing stability of the heater for a semiconductor manufacturing apparatus.

A primary object of the present invention is to provide a heater for a semiconductor manufacturing apparatus, which can improve the volume resistivity of a ceramic base, and can be stably manufactured.

[1] According to at least one embodiment of the present invention, there is provided a heater for a semiconductor manufacturing apparatus including a ceramic base and a heating element. The ceramic base contains aluminum nitride. The heating element is embedded in the ceramic base. The ceramic base contains two or more kinds of rare earth elements and contains Yb as one of the rare earth elements. A total content ratio of the rare earth elements in the ceramic base is 4.5 mass % or less in terms of oxide. A content ratio of Yb in the ceramic base is 0.3 mass % or more and 1.3 mass % or less in terms of oxide.

[2] In the heater for a semiconductor manufacturing apparatus according to the above-mentioned item [1], a volume resistivity of the ceramic base at 500° C. may be 1×10⁹ Ω·cm or more.

[3] In the heater for a semiconductor manufacturing apparatus according to the above-mentioned item [1] or [2], the ceramic base may further contain Y as one of the rare earth elements.

[4] In the heater for a semiconductor manufacturing apparatus according to any one of the above-mentioned items [1] to [3], a content ratio of Ca in the ceramic base may be 300 ppm or less.

[5] In the heater for a semiconductor manufacturing apparatus according to any one of the above-mentioned items [1] to [4], a content ratio of Ca in the ceramic base may be 80 ppm or more.

[6] In the heater for a semiconductor manufacturing apparatus according to any one of the above-mentioned items [1] to [5], the ceramic base may further contain Ca and Si. In this case, a mass ratio of Si to Ca in the ceramic base may be 0.060 or more and 0.20 or less. A mass ratio of Yb to Y in the ceramic base may be 0.10 or more and 0.45 or less.

### BRIEF DESCRIPTION OF THE DRAWINGS

FIG. 1 is a schematic configuration diagram of a heater for a semiconductor manufacturing apparatus according to at least one embodiment of the present invention.

### DESCRIPTION OF THE EMBODIMENTS

Embodiments of the present invention are described below. However, the present invention is not limited to these embodiments. In addition, for clearer illustration, some widths, thicknesses, shapes, and the like of respective portions may be schematically illustrated in the drawings in comparison to the embodiments. However, the widths, the thicknesses, the shapes, and the like are each merely an example, and do not limit the understanding of the present invention.

### A. Outline of Heater for Semiconductor Manufacturing Apparatus

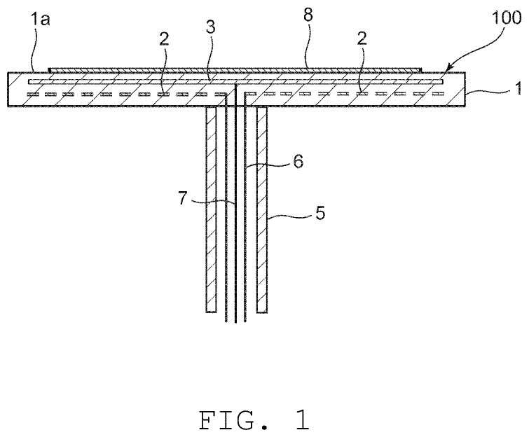

FIG. 1 is a schematic cross-sectional view of a heater for a semiconductor manufacturing apparatus according to at least one embodiment of the present invention. A heater 100 for a semiconductor manufacturing apparatus according to at least one embodiment of the present invention is typically capable of supporting and heating a semiconductor substrate 8.

The heater 100 for a semiconductor manufacturing apparatus includes a ceramic base 1 and a heating element 2. The ceramic base 1 contains aluminum nitride (AlN) as a main component. The ceramic base 1 contains two or more kinds of rare earth elements and contains Yb as one of the rare earth elements. The total content ratio of the rare earth elements in the ceramic base 1 is 4.5 mass % or less in terms of oxide. In addition, the content ratio of Yb in the ceramic base 1 is 0.3 mass % or more and 1.3 mass % or less in terms of oxide. The heating element 2 is embedded in the ceramic base 1.

According to such configuration, the total content ratio of the rare earth elements in the ceramic base is 4.5 mass % or less, and hence the difference between the linear expansion coefficients of the ceramic base and the heating element can be stably reduced. In addition, the ceramic base contains 0.3 mass % or more and 1.3 mass % or less of Yb among the two or more kinds of rare earth elements, and hence the volume resistivity of the ceramic base can be sufficiently increased. In addition, when the content ratio of Yb in the ceramic base falls within such range, color unevenness in the ceramic base can be sufficiently suppressed.

Accordingly, a heater for a semiconductor manufacturing apparatus including a ceramic base having an excellent volume resistivity can be stably manufactured.

The total content ratio of the rare earth elements in the ceramic base 1 is, for example, 0.5 mass % or more, preferably 1.0 mass % or more, more preferably 3.0 mass % or more in terms of oxide. When the total content ratio of the rare earth elements in the ceramic base falls within such ranges, the volume resistivity of the ceramic base can be stably increased.

The content ratio of each component in the ceramic base is measured by inductively coupled plasma atomic emission spectroscopy (ICP-AES), for example.

The content ratio of Yb in the ceramic base 1 is, for example, 0.3 mass % or more, preferably 0.6 mass % or more, more preferably 0.9 mass % or more in terms of oxide. When the content ratio of Yb in the ceramic base falls within such ranges, color unevenness in the ceramic base can be stably suppressed, and the volume resistivity of the ceramic base can be more stably increased.

In at least one embodiment of the present invention, the ceramic base 1 further contains Y as one of the rare earth elements. When the ceramic base contains Yb and Y in combination, improvement of the volume resistivity of the ceramic base and improvement of manufacturing stability of the heater for a semiconductor manufacturing apparatus can both be stably achieved.

The content ratio of Y in the ceramic base 1 is, for example, 2.0 mass % or more, preferably 2.5 mass % or more in terms of oxide. Meanwhile, the content ratio of Y in the ceramic base 1 is, for example, 4.0 mass % or less, or for example, 3.5 mass % or less.

The mass ratio (Yb:Y) between Yb and Y in the ceramic base 1 is, for example, from 1:2 to 1:10, preferably from 1:2 to 1:7.5, more preferably from 1:2 to 1:5.

The mass ratio (Yb/Y) of Yb to Y in the ceramic base 1 is, for example, 0.08 or more, preferably 0.10 or more, more preferably 0.13 or more, still more preferably 0.20 or more, still further more preferably 0.25 or more, particularly preferably 0.30 or more. Meanwhile, the mass ratio (Yb/Y) of Yb to Y in the ceramic base 1 is, for example, 0.50 or less, preferably 0.45 or less, more preferably 0.43 or less.

When the mass ratio of Yb to Y falls within such ranges, the volume resistivity of the ceramic base can be stably increased.

The ceramic base 1 may further contain another rare earth element in addition to Yb and Y, and may contain only Yb and Y as the rare earth elements.

In at least one embodiment of the present invention, the ceramic base 1 contains only Yb and Y as the rare earth elements, and is substantially free of any other rare earth element. The content ratio of the other rare earth element in the ceramic base 1 is, for example, 0.5 mass % or less in terms of oxide. Consequently, improvement of the volume resistivity of the ceramic base and improvement of manufacturing stability of the heater for a semiconductor manufacturing apparatus can both be more stably achieved. An example of the other rare earth element is Ce.

The content ratio of AlN in the ceramic base 1 is, for example, 90.0 mass % or more, preferably 93.0 mass % or more. Meanwhile, the content ratio of AlN in the ceramic base 1 is, for example, 99.0 mass % or less, preferably 95.0 mass % or less.

The ceramic base 1 may further contain a trace component in addition to AlN and the rare earth elements. Examples of the trace component include O, C, Ti, Ca, Mg, Si, and Fe. One kind of the trace component may be incorporated into the ceramic base alone, or two or more kinds thereof may be incorporated in combination.

The content ratio of the trace component in the ceramic base 1 is, for example, 0.1 mass % or less, preferably 0.05 mass % or less.

In particular, the content ratio of Ca in the ceramic base 1 is, for example, 300 ppm or less, preferably 280 ppm or less, more preferably 230 ppm or less. When the content ratio of Ca in the ceramic base is equal to or less than such upper limits, the volume resistivity of the ceramic base can be stably improved.

Meanwhile, the content ratio of Ca in the ceramic base 1 is, for example, 0 ppm or more, preferably 30 ppm or more, more preferably 80 ppm or more, still more preferably 120 ppm or more, still further more preferably 140 ppm or more, particularly preferably 200 ppm or more. When the ceramic base contains Yb and Ca at the above-mentioned ratios, respectively, the volume resistivity of the ceramic base can be significantly increased.

In at least one embodiment of the present invention, the ceramic base 1 contains Ca and Si in addition to AlN and the rare earth elements.

The content ratio of Si in the ceramic base 1 is, for example, 40 ppm or less, preferably 30 ppm or less, more preferably 25 ppm or less. Meanwhile, the content ratio of Si in the ceramic base 1 is, for example, 0 ppm or more, preferably 5 ppm or more, more preferably 10 ppm or more.

The mass ratio (Si/Ca) of Si to Ca in the ceramic base 1 is, for example, 0.400 or less, preferably 0.300 or less, more preferably 0.200 or less, still more preferably 0.157 or less, still further more preferably 0.100 or less. When the ceramic base contains Yb at the above-mentioned ratios, and the ratio Si/Ca is equal to or less than such upper limits, the volume resistivity of the ceramic base can be significantly increased.

Meanwhile, the mass ratio (Si/Ca) of Si to Ca in the ceramic base 1 is, for example, 0.030 or more, preferably 0.050 or more, more preferably 0.060 or more, still more preferably 0.065 or more.

The ceramic base 1 as described above has a relatively high volume resistivity.

The volume resistivity of the ceramic base 1 at 500° C. is, for example, 5.0×10⁸ Ω·cm or more, preferably 1.0×10⁹ Ω·cm or more, more preferably 5.0×10⁹ Ω·cm or more, still more preferably 7.5×10⁹ Ω·cm or more. Meanwhile, the upper limit of the volume resistivity of the ceramic base 1 at 500° C. is typically 1.0×10¹⁰ Ω·cm. The volume resistivity at 500° C. is measured in accordance with JIS C2141-1992, for example.

The thermal conductivity of the ceramic base 1 at 500° C. is, for example, from 60 W/m·K to 90 W/m·K, preferably from 70 W/m. K to 80 W/m·K. The thermal conductivity of the ceramic base at 500° C. is measured in accordance with JIS R1611, for example.

The average linear expansion coefficient of the ceramic base 1 in the temperature range of from 50° C. to 1,000° C. is, for example, from 5.3 ppm/° C. to 5.9 ppm/° C., preferably from 5.5 ppm/° C. to 5.8 ppm/° C. The average linear expansion coefficient is measured in accordance with JIS R1618, for example.

The heating element 2 contains any appropriate metal. Examples of the metal include tantalum (Ta), tungsten (W), molybdenum (Mo), tungsten carbide (WC), titanium nitride (TiN), platinum (Pt), rhenium (Re), hafnium (Hf), and an alloy thereof.

Among the metals, W, Mo, and a W—Mo alloy are preferred.

When the heating element contains such metal, the linear expansion coefficient of the ceramic base and the linear expansion coefficient of the heating element described above can be stably brought close to each other. Accordingly, manufacturing stability of the heater for a semiconductor manufacturing apparatus can be further improved.

The average linear expansion coefficient of the heating element 2 in the temperature range of from 50° C. to 1,000° C. is, for example, from 5.4 ppm/° C. to 6.0 ppm/° C., preferably from 5.6 ppm/° C. to 5.9 ppm/° C.

In addition, the absolute value of the difference between the average linear expansion coefficients of the ceramic base 1 and the heating element 2 in the temperature range of from 50° C. to 1,000° C. is, for example, 0.5 ppm/° C. or less, preferably 0.3 ppm/° C. or less. Meanwhile, the lower limit of the absolute value of the difference between the average linear expansion coefficients of the ceramic base 1 and the heating element 2 is typically 0.1 ppm/° C.

### B. Details of Heater for Semiconductor Manufacturing Apparatus

Details of each member of the heater for a semiconductor manufacturing apparatus are described below.

### B-1. Ceramic Base

The ceramic base 1 may have any appropriate shape in accordance with an application of the heater for a semiconductor manufacturing apparatus. A typical example of the shape of the ceramic base 1 is a plate shape. The ceramic base 1 preferably has a disc shape.

The ceramic base 1 typically has a mounting surface 1a on which the semiconductor substrate 8 can be mounted. The mounting surface 1a is one surface in the thickness direction of the ceramic base 1.

The thickness of the ceramic base 1 is, for example, from 10 mm to 40 mm.

As described above, the ceramic base 1 contains AlN as a main component and contains, as a secondary component, two or more kinds of rare earth elements including Yb. Such ceramic base 1 typically contains an AlN crystal phase and an ytterbium aluminate crystal phase.

In at least one embodiment of the present invention, the AlN crystal phase has a polycrystalline structure in which a plurality of AlN crystal grains are bonded to each other. The average grain diameter of the plurality of AlN crystal grains is, for example, from 2 μm to 5 μm, preferably from 3 μm to 4.5 μm.

The ytterbium aluminate crystal phase is typically present at a grain boundary between AlN grains.

When the rare earth elements include yttrium (Y) in addition to Yb, the ceramic base 1 further contains an yttrium aluminate crystal phase. The yttrium aluminate crystal phase is typically present at a grain boundary between AlN grains.

The ceramic base 1 may further contain another crystal phase in addition to the AlN crystal phase, the ytterbium aluminate crystal phase, and the yttrium aluminate crystal phase, and may be substantially free of any other crystal phase.

In at least one embodiment of the present invention, the ceramic base 1 contains, as crystal phases, only the AlN crystal phase, the ytterbium aluminate crystal phase, and the yttrium aluminate crystal phase, and is substantially free of any other crystal phase.

The porosity of the ceramic base 1 is, for example, 1% or less. The porosity is measured in accordance with JIS R1634, for example.

The relative density of the ceramic base 1 is, for example, from 3.2 g/cc to 3.4 g/cc, preferably from 3.25 g/cc to 3.35 g/cc. The relative density of a ceramic base is the bulk density of the ceramic base relative to the theoretical density thereof. The bulk density of the ceramic base is measured in accordance with JIS R1634, for example.

The ceramic base 1 described above is supported by a ceramic shaft 5 in the illustrated example. The ceramic shaft 5 is connected to the surface of the ceramic base 1 on the side opposite to the mounting surface 1a.

The ceramic shaft 5 has any appropriate shape. In at least one embodiment of the present invention, the ceramic shaft 5 has a cylindrical shape extending in the thickness direction of the ceramic base 1. In the illustrated example, the axis of the ceramic shaft 5 and the center of the ceramic base 1 substantially coincide with each other as viewed in the thickness direction of the ceramic base 1. The ceramic shaft 5 is formed of any appropriate ceramic material, but is preferably a ceramic shaft formed of the same material as that of the ceramic base, that is, containing aluminum nitride, from the viewpoint of reducing a difference in thermal expansion from the ceramic base.

### B-2. Heating Element

The heating element 2 is configured to generate heat when a voltage is applied thereto. The number of heating elements 2 embedded in the ceramic base 1 is not particularly limited. A plurality of heating elements 2 may be embedded in the ceramic base 1. In this case, the plurality of heating elements 2 are positioned apart from one another in the thickness direction of the ceramic base 1.

In the illustrated example, one heating element 2 is embedded in the ceramic base 1.

The heating element 2 has any appropriate shape. Examples of the heating element 2 include coil-shaped, zigzag-shaped, and mesh-shaped heating elements. The dimension (wire diameter) of the heating element 2 in the thickness direction of the ceramic base 1 is, for example, from 0.3 mm to 1.0 mm, preferably from 0.4 mm to 0.7 mm.

The volume resistivity of the heating element 2 at 500° C. is, for example, 1.9×10⁻⁵ Ω·cm or less, preferably 1.8×10⁻⁵ Ω·cm or less. Meanwhile, the lower limit of the volume resistivity of the heating element 2 at 500° C. is typically 1.6×10⁻⁵ Ω·cm.

In the illustrated example, a first power feeding rod 6 is electrically connected to the heating element 2. A voltage may be applied to the heating element 2 via the first power feeding rod 6. The first power feeding rod 6 is formed of any appropriate conductive material. The first power feeding rod 6 is electrically connected to the heating element 2 through an internal space of the ceramic shaft 5.

### B-3. Internal Electrode

In at least one embodiment of the present invention, the heater 100 for a semiconductor manufacturing apparatus further includes an internal electrode 3. The internal electrode 3 is embedded in the ceramic base 1. In the illustrated example, the internal electrode 3 is positioned between the mounting surface 1a and the heating element 2 in the thickness direction of the ceramic base 1.

The internal electrode 3 typically functions as an ESC electrode. In a case where the internal electrode 3 functions as an ESC electrode, when a DC voltage is applied to the internal electrode 3 under a state in which the semiconductor substrate 8 is mounted on the mounting surface 1a, the internal electrode 3 becomes either positively or negatively charged depending on the polarity of the DC voltage applied, and the corresponding opposite charge (positive or negative) inherent in the semiconductor substrate 8 moves to the mounting surface 1a side of the semiconductor substrate 8. Consequently, Johnson-Rahbek (JR) force is generated between the semiconductor substrate 8 and the internal electrode 3, and the semiconductor substrate 8 is chucked by the ceramic base 1.

Although not illustrated in the drawing, the heater 100 for a semiconductor manufacturing apparatus may include a plurality of internal electrodes 3.

In at least one embodiment of the present invention, the internal electrode 3 functions as a radio-frequency electrode (that is, a RF electrode) for plasma treatment. That is, the internal electrode 3 preferably functions as a RF/ESC electrode. Examples of the plasma treatment include film forming treatment and etching treatment.

When the semiconductor substrate 8 on the mounting surface 1a is subjected to such plasma treatment, an upper electrode is arranged on the side of the semiconductor substrate 8 opposite to the internal electrode 3. When radio-frequency power is supplied to the internal electrode 3 in this state, processing gas can be excited to generate plasma in the space between the ceramic base 1 and the upper electrode. The plasma generated in this manner is used for plasma treatment on the semiconductor substrate 8.

The internal electrode 3 may have any appropriate shape. The internal electrode 3 typically has a plate shape. In at least one embodiment of the present invention, the internal electrode 3 has a shape similar to the outer shape of the ceramic base 1 when viewed in the thickness direction of the ceramic base 1. In the illustrated example, the center of the internal electrode 3 and the center of the ceramic base 1 are substantially aligned when viewed in the thickness direction of the ceramic base 1.

The thickness of the internal electrode 3 is, for example, from 0.2 mm to 0.8 mm.

The internal electrode 3 typically contains the same metal as that of the heating element 2 described above. Accordingly, the range of the average linear expansion coefficient of the internal electrode 3 in the temperature range of from 50° C. to 1, 000° C. is, for example, the same as the range of the average linear expansion coefficient of the heating element 2 described above. In addition, the range of the absolute value of the difference between the average linear expansion coefficients of the ceramic base 1 and the internal electrode 3 in the temperature range of from 50° C. to 1,000° C. is, for example, the same as the range of the absolute value of the difference between the average linear expansion coefficients of the ceramic base 1 and the heating element 2 described above. Consequently, breakage such as a crack can be prevented from occurring in the ceramic base in manufacturing the heater for a semiconductor manufacturing apparatus even when the heater for a semiconductor manufacturing apparatus includes an internal electrode.

In the illustrated example, a second power feeding rod 7 is electrically connected to the internal electrode 3. The above-mentioned voltage (or radio-frequency power) may be applied to the internal electrode 3 via the second power feeding rod 7. The second power feeding rod 7 is typically formed of the same metal as that of the internal electrode 3. The second power feeding rod 7 is electrically connected to the internal electrode 3 through the internal space of the ceramic shaft 5.

### C. Method of manufacturing Heater for Semiconductor Manufacturing Apparatus

Next, a method of manufacturing a heater for a semiconductor manufacturing apparatus according to at least one embodiment of the present invention is described.

The method of manufacturing a heater for a semiconductor manufacturing apparatus according to at least one embodiment of the present invention includes: a mixing step of mixing raw material powders of a ceramic base to provide a raw material mixture; a molding step of preparing, from the raw material mixture obtained in the mixing step and a heating element, a molded body in which the heating element is embedded; and a firing step of firing the molded body obtained in the molding step.

### C-1. Mixing Step

In the mixing step, AlN powder and two or more kinds of rare earth element powders are mixed to prepare a powder mixture. In at least one embodiment of the present invention, AlN powder, Yb₂O₃ powder, and Y₂O₃ powder are mixed to prepare a raw material mixture.

The AlN powder and/or the rare earth element powders may contain the trace component described above. In addition, the trace component may be separately added to the raw material mixture as required.

The addition amount of the Yb₂O₃ powder is, for example, 0.05 part by mass or more, preferably 0.1 part by mass or more, more preferably 0.5 part by mass or more, still more preferably 0.8 part by mass or more based on 100 parts by mass of the AlN powder. Meanwhile, the upper limit of the addition amount of the Yb₂O₃ powder is typically 1.3 parts by mass based on 100 parts by mass of the AlN powder.

The addition amount of the Y₂O₃ powder is, for example, 0.5 part by mass or more, preferably 1.0 part by mass or more, more preferably 3.0 parts by mass or more based on 100 parts by mass of AlN. Meanwhile, the upper limit of the addition amount of Y₂O₃ is typically 4.3 parts by mass based on 100 parts by mass of the AlN powder.

Any appropriate mixing device may be used in the mixing step. Examples of the mixing device usable in the mixing step include a ball mill, a bead mill, and a vibrational mill, and a ball mill is preferred.

A mixing method in the mixing step may be a dry mixing process or a wet mixing process. In at least one embodiment of the present invention, a dry mixing process is carried out in the mixing step.

Environmental conditions in the mixing step are not particularly limited. The mixing step is typically carried out at normal temperature (25° C.) under normal pressure (0.1 MPa).

The duration of the mixing step is freely and appropriately set. The duration of the mixing step is, for example, from 1 hour to 30 hours.

In the manner described above, the raw material mixture containing AlN powder and two or more kinds of rare earth element powders (typically, Yb₂O₃ powder and Y₂O₃ powder) is prepared. When the mixing step is a dry mixing process, the raw material mixture takes a powdery form, and when the mixing step is a wet mixing process, the raw material mixture takes a slurry form.

The raw material mixture is granulated as required. A granulation method is, for example, a spray dryer.

Consequently, a granulated product (raw material granules) of the raw material mixture is prepared.

### C-2. Molding Step

Then, in the molding step, the raw material mixture is molded by any appropriate molding method under a state in which the heating element 2 preliminarily prepared is embedded at a desired position in the raw material mixture.

Examples of the molding method include press molding, sheet molding, and cold isostatic pressing (CIP), and press molding is preferred. The pressure in the press molding is, for example, from 10 kgf/cm² to 500 kgf/cm².

Consequently, a molded body having a desired shape is prepared.

### C-3. Firing Step

In the firing step, the molded body is fired by any appropriate firing method. Typically, the molded body is fired under a vacuum or a non-oxidizing atmosphere. For example, the temperature is raised from normal temperature (23° C.) to a predetermined firing temperature, and the firing temperature is then maintained for a predetermined firing time.

The firing temperature is, for example, from 1, 600° C. to 1,900° C., preferably from 1,650° C. to 1,850° C. The firing time is, for example, from 0.5 hour to 20 hours.

Examples of the firing method include hot pressing and hot isostatic pressing (HIP), and hot pressing is preferred.

In the hot pressing, the molded body is typically placed in a hot pressing die (for example, a graphite mold), heated to the firing temperature as described above, and pressed under a predetermined pressure. The pressure in the hot pressing is, for example, from 5 MPa to 50 MPa.

As described above, a heater for a semiconductor manufacturing apparatus including the ceramic base and the heating element embedded in the ceramic base is manufactured.

### EXAMPLES

The present invention is specifically described below by way of Examples and Comparative Examples. However, the present invention is not limited by these Examples. Measurement methods for characteristics are as described below.

### (1) Measurement of Average Linear Expansion Coefficients of Ceramic Base and Heating Element

The average linear expansion coefficients of a ceramic base and a heating element included in a heater for a semiconductor manufacturing apparatus manufactured in each of Examples and Comparative Examples were measured in accordance with JIS R1618. The respective average linear expansion coefficients of the ceramic base and the heating element and the difference between these average linear expansion coefficients are shown in Table 1.

### (2) Measurement of Volume Resistivity of Ceramic Base

The volume resistivity of the ceramic base included in the heater for a semiconductor manufacturing apparatus manufactured in each of Examples and Comparative Examples was measured in accordance with JIS C2141. The results thereof are shown in Table 1.

### Example 1

95 Parts by mass of AlN powder, 3 parts by mass of Y₂O₃ powder, and 1.3 parts by mass of Yb₂O₃ powder were loaded into a ball mill, followed by dry mixing for 10 hours. Thus, a powder mixture (raw material mixture) was obtained. After that, the powder mixture was granulated through spray drying.

In addition, a heating element made of Mo, the heating element having a coil shape, was prepared. Then, a predetermined mold was filled with granules of the powder mixture, and the heating element was embedded in a desired position.

After that, the granules of the powder mixture filling the mold were uniaxially pressed to provide a molded body having a disc shape. The pressure in the uniaxial pressing was 100 kgf/cm². The diameter of the molded body was 350 mm. The thickness of the molded body was 50 mm.

Then, the molded body was fired by hot pressing. More specifically, first, the molded body was accommodated in a hot pressing die formed of graphite, and the molded body was fired for 5 hours at 1,850° C. by hot pressing. The pressure in the hot pressing was 10 MPa.

In the manner described above, a heater for a semiconductor manufacturing apparatus including a ceramic base and a heating element was manufactured. After that, the heater for a semiconductor manufacturing apparatus was cooled to room temperature (25° C.).

The ceramic base contained Ca and Si as trace components in addition to AlN, Yb, and Y. The respective content ratios of yttrium (Y) and ytterbium (Yb) in terms of oxide, the total content ratio of the rare earth elements, and the content ratios of the trace components are shown in Table 1 below.

### Example 2

A heater for a semiconductor manufacturing apparatus was manufactured in the same manner as in Example 1 except that: the amount of the Y₂O₃ powder was changed to 3.5 parts by mass; the amount of the Yb₂O₃ powder was changed to 0.9 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Example 3

A heater for a semiconductor manufacturing apparatus was manufactured in the same manner as in Example 1 except that: the amount of the Yb₂O₃ powder was changed to 0.6 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Example 4

A heater for a semiconductor manufacturing apparatus was manufactured in the same manner as in Example 1 except that: the amount of the Yb₂O₃ powder was changed to 0.4 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Example 5

A heater for a semiconductor manufacturing apparatus was manufactured in the same manner as in Example 1 except that: the amount of the Y₂O₃ powder was changed to 2.0 parts by mass; the amount of the Yb₂O₃ powder was changed to 0.6 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Example 6

A heater for a semiconductor manufacturing apparatus was manufactured in the same manner as in Example 1 except that: the amount of the Y₂O₃ powder was changed to 2.9 parts by mass; the amount of the Yb₂O₃ powder was changed to 0.3 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Example 7

A heater for a semiconductor manufacturing apparatus was manufactured in the same manner as in Example 5 except that: the amount of the Yb₂O₃ powder was changed to 1.0 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Example 8

A heater for a semiconductor manufacturing apparatus was manufactured in the same manner as in Example 1 except that: the amount of the Yb₂O₃ powder was changed to 1.0 part by mass; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Comparative Example 1

A heater for a semiconductor manufacturing apparatus was manufactured in the same manner as in Example 1 except that: the powder mixture was prepared by mixing 96 parts by mass of the AlN powder and 4 parts by mass of the Y₂O₃ powder; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Comparative Example 2

A heater for a semiconductor manufacturing apparatus was manufactured in the same manner as in Example 1 except that: the powder mixture was prepared by mixing 96 parts by mass of the AlN powder and 4 parts by mass of the Yb₂O₃ powder; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Comparative Example 3

A heater for a semiconductor manufacturing apparatus was manufactured in the same manner as in Example 1 except that: the powder mixture was prepared by mixing 95 parts by mass of the AlN powder, 3.0 parts by mass of the Y₂O₃ powder, and 0.2 part by mass of the Yb₂O₃ powder; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

### Comparative Example 4

A heater for a semiconductor manufacturing apparatus was manufactured in the same manner as in Example 1 except that: the powder mixture was prepared by mixing 96 parts by mass of the AlN powder, 2.6 parts by mass of the Y₂O₃ powder, and 1.5 parts by mass of the Yb₂O₃ powder; and the content ratios of the trace components (Ca and Si) were adjusted to the values shown in Table 1. The respective content ratios of yttrium (Y) and ytterbium (Yb) in terms of oxide, the total content ratio of the rare earth elements, and the content ratios of the trace components are shown in Table 1 below.

TABLE 1

| | | | Total | | | | | | | |
|---|---|---|---|---|---|---|---|---|---|---|
| | | | content | | | | | | | |
| | | | ratio | | | | | | | |
| | | | (wt % ) of | | | | | | VR*¹ | |
| | | | rare | | | | | | (Ω · cm) | |
| | Yb₂O₃ | Y₂O₃ | earth | Yb₂O₃: | Ca | Si | | Yb₂O₃: | at | |
| Component | (wt % ) | ( wt % ) | elements | Y₂O₃ | (ppm | (ppm) | Si/Ca | Y₂O₃ | 500° C. | APR*² |
| Example 1 | 1.3 | 3.0 | 4.3 | 1:2.3 | 230 | 15 | 0.065 | 0.43 | 6.1 × 10⁹ | OK |
| Example 2 | 0.9 | 3.5 | 4.4 | 1:3.9 | 180 | 19 | 0.106 | 0.26 | 5.2 × 10⁹ | OK |
| Example 3 | 0.6 | 3.0 | 3.6 | 1:5 | 280 | 20 | 0.071 | 0.20 | 2.6 × 10⁹ | OK |
| Example 4 | 0.4 | 3.0 | 3.4 | 1:7.5 | 250 | 18 | 0.072 | 0.13 | 1.0 × 10⁹ | OK |
| Example 5 | 0.6 | 2.0 | 2.6 | 1:3.3 | 140 | 22 | 0.157 | 0.30 | 5.3 × 10⁹ | OK |
| Example 6 | 0.3 | 2.9 | 3.2 | 1:10 | 110 | 16 | 0.145 | 0.10 | 1.2 × 10⁹ | OK |
| Example 7 | 1.0 | 2.0 | 3.0 | 1:2 | 260 | 22 | 0.085 | 0.50 | 7.6 × 10⁸ | OK |
| Example 8 | 1.0 | 3.0 | 4.0 | 1:3 | 50 | 19 | 0.380 | 0.33 | 8.8 × 10⁸ | OK |
| Comparative | 0.0 | 4.0 | 4.0 | ∞ | 310 | 16 | 0.052 | — | 3.5 × 10⁸ | OK |
| Example 1 | | | | | | | | | | |
| Comparative | 4.0 | 0.0 | 4.0 | 1:0 | 240 | 16 | 0.067 | — | 7.7 × 10⁹ | NG |
| Example 2 | | | | | | | | | | |
| Comparative | 0.2 | 3.0 | 3.2 | 1:15 | 320 | 21 | 0.066 | 0.07 | 4.0 × 10⁸ | OK |
| Example 3 | | | | | | | | | | |
| Comparative | 1.5 | 2.6 | 4.1 | 1:1.7 | 330 | 19 | 0.058 | 0.58 | 3.0 × 10⁹ | NG |
| Example 4 | | | | | | | | | | |

*¹Volume resistivity
*²Appearance

### Evaluation

Table 1 shows the relationship between the volume resistivity of each ceramic base at 500° C. and the appearance of the ceramic base. The volume resistivity of the ceramic base can be improved, and color unevenness in the ceramic base can be sufficiently suppressed (appearance is rated as OK) in the heater for a semiconductor manufacturing apparatus of each of Examples 1 to 8. Accordingly, it is found that a heater for a semiconductor manufacturing apparatus having an excellent volume resistivity can be stably manufactured.

The heater for a semiconductor manufacturing apparatus of each of Comparative Examples 2 and 4 is unacceptable as a product (appearance is rated as NG) because color unevenness in the ceramic base is prominent, though the volume resistivity of the ceramic base is relatively high.

The heater for a semiconductor manufacturing apparatus according to at least one embodiment of the present invention is typically used in semiconductor manufacturing, and in particular, can be suitably used as a ceramic heater that holds and heats a semiconductor substrate.

According to at least one embodiment of the present invention, the heater for a semiconductor manufacturing apparatus, which can improve the volume resistivity of a ceramic base, and can be stably manufactured, can be achieved.

What is claimed is:

1. A heater for a semiconductor manufacturing apparatus, comprising:
a ceramic base including aluminum nitride; and
a heating element embedded in the ceramic base,
wherein the ceramic base includes two or more kinds of rare earth elements and includes Yb as one of the rare earth elements,
wherein a total content ratio of the rare earth elements in the ceramic base is 4.5 mass % or less in terms of oxide, and
wherein a content ratio of Yb in the ceramic base is 0.3 mass % or more and 1.3 mass % or less in terms of oxide.

2. The heater for a semiconductor manufacturing apparatus according to claim 1, wherein a volume resistivity of the ceramic base at 500° C. is 1×10⁹ Ω·cm or more.

3. The heater for a semiconductor manufacturing apparatus according to claim 1, wherein the ceramic base includes Y as one of the rare earth elements.

4. The heater for a semiconductor manufacturing apparatus according to claim 1, wherein a content ratio of Ca in the ceramic base is 300 ppm or less.

5. The heater for a semiconductor manufacturing apparatus according to claim 1, wherein a content ratio of Ca in the ceramic base is 80 ppm or more.

6. The heater for a semiconductor manufacturing apparatus according to claim 1,
wherein the ceramic base further includes Ca and Si,
wherein a mass ratio of Si to Ca in the ceramic base is 0.060 or more and 0.20 or less, and
wherein a mass ratio of Yb to Y in the ceramic base is 0.10 or more and 0.45 or less.

7. A heater for a semiconductor manufacturing apparatus, comprising:
a ceramic base including aluminum nitride; and
a heating element embedded in the ceramic base,
wherein the ceramic base includes two or more kinds of rare earth elements and includes Yb as one of the rare earth elements,
wherein a total content ratio of the rare earth elements in the ceramic base is 4.5 mass % or less in terms of oxide,
wherein a content ratio of Yb in the ceramic base is 0.3 mass % or more and 1.3 mass % or less in terms of oxide,
wherein a volume resistivity of the ceramic base at 500° C. is 1×10⁹ Ω·cm or more,
wherein the ceramic base includes Y as one of the rare earth elements, Ca, and Si,
wherein a content ratio of Ca in the ceramic base is 80 ppm or more and 300 ppm or less,
wherein a mass ratio of Si to Ca in the ceramic base is 0.060 or more and 0.20 or less, and
wherein a mass ratio of Yb to Y in the ceramic base is 0.10 or more and 0.45 or less.
